(19) United States
(12) Patent Application Publication
(10) Pub. No.: US 2016/0079472 A1
(43) Pub. Date: Mar. 17, 2016

(54) SEMICONDUCTOR DEVICES AND RELATED METHODS

(71) Applicant: Cree, Inc., Durham, NC (US)

(72) Inventors: Arthur Fong-Yuen Pun, Durham, NC (US); David B. Slater, JR., Baskerville, VA (US)

(21) Appl. No.: 14/486,701

(22) Filed: Sep. 15, 2014

(51) Int. Cl. H01L 33/20; H01L 33/62

(52) U.S. Cl. CPC H01L 33/20; H01L 33/62; H01L 2933/0033; H01L 2933/0066

(57) ABSTRACT

Semiconductor devices and related methods are disclosed. In one aspect, a semiconductor device includes a substrate and an active area disposed over the substrate. The active area includes at least one or more corner region having a non-orthogonal angled edge. A method of providing a semiconductor device is also provided. The method includes providing a substrate and fabricating an active area over the substrate. The active area includes at least one or more corner region with a non-orthogonal angled edge. LED chips and methods herein have a reduced sensitivity to corner cracking, fracturing, or chipping.

### TECHNICAL FIELD

The subject matter herein relates generally to semiconductor devices, and more particularly to light emitting diode (LED) chips and related methods having a reduced sensitivity to corner fractures.

### BACKGROUND

Many different types of semiconductor devices, including solid state lighting sources comprise a substrate and one or more layers (e.g., active areas, mesas) disposed over the substrate. Semiconductor devices include, for example and are not limited to, various types of diodes (light emitting, laser, Schottky, Zener and/or rectifier diodes), integrated circuits, integrated circuit devices, sensors, photocells, field-effect transistors (FETs), MOSFETs, monolithic microwave integrated circuits (MMICs), high-electron-mobility transistors (HEMTs), radio frequency (RF) devices, micro-devices, broadband devices, etc.

One exemplary and non-limiting semiconductor device is a light emitting diode (LED) chip. LED chips are used in a variety of lighting devices, products, components, and/or fixtures for general commercial, industrial, and personal lighting applications. Advantages of using LED products include both an increase in energy savings and product lifetimes.

Conventional LED chips are susceptible to chipping, fracturing, and/or breaking during any one of several manufacturing processes, operations, and/or steps. For example, LED chips are susceptible to chipping during die (e.g., chip) singulation processes, such as a sawing and/or breaking process, in which a plurality of individual LED chips become physically separated from a wafer. Chipping may also occur during inspection processes (e.g., manual or automated), during pick-and-place processes, and/or by mere wafer and/or die sheet handling during or between manufacturing processes. Chipping typically occurs along edges or corners of individual LED chips. Corners of LED chips are particularly susceptible to breakage or chipping, as the corners are the most physically sensitive areas of the chip body and are also prone to more contact than other surfaces.

Chipping along corners or edges of LED chips is problematic, as the chipping or breakage can extend into the PN junction (also referred to as the “mesa” or “active area”) of the LED chip. Chipping is also problematic, as it occurs irrespective of the LED chip size and/or shape, thereby affecting LED chips of all sizes and/or shapes. Damage to the LED chip mesa or junction typically results in leaky, shorted out, and/or dark chips. Leaky chips can result in catastrophic failure of an LED device, and shorted out or dark chips may simply fail to illuminate. To date, there is no proven method for improving manufacturing yields and/or reducing failure rates associated with LED chips by preventing chipped edges and/or mesas. There is also no proven method for lessoning the effect of chipped edges and/or mesas. Accordingly, a need remains for providing robust LED chips having an improved resistance to failure or leakage and a reduced sensitivity to corner fractures, should corner fractures or chips occur.

FIGS. 1A and 1B illustrate an LED (i.e., an LED chip), generally designated “LED”, as known in the art, which is susceptible to failure as a result of corner or edge chipping. LED can comprise a substrate S, over which a plurality of p- and n- type layers (e.g., epitaxial layers) are grown and fabricated. For illustration purposes, the junction of the p- and n-type layers is illustrated as a single layer, which is an active region or mesa M. Mesa M is configured to illuminate upon electrical current being applied thereto via current passed between anode A and cathode C members or components. Anode and cathode members A and C, respectively, can be disposed over and in electrical communication with mesa M.

As FIGS. 1A and 1B illustrate, substrate S and mesa M comprise a same shape and/or a same number of edges. Substrate S and mesa M can each comprise one or more corner areas or regions, generally designated, R, where edges forming each of the respective substrate S and mesa M are orthogonally disposed and form right angles.

During any one of several manufacturing processes, one or more chips or fractures, generally designated F can occur. Chip or fracture F may form proximate corner regions R of LED, and oftentimes originate within substrate S. The fracture F can then extend into and/or touch or contact one or more portions of mesa M, for example, due to the cleavage path crystallography or structure of substrate S. When this occurs, LED fails, or becomes leaky and then ultimately fails during operation of a lighting device or fixture.

Despite the availability of various semiconductor devices and methods in the marketplace, a need remains for providing improved devices that are robust and/or insensitive to chipping, breaking, and/or fracturing, not limited to corner chipping.

### SUMMARY

In accordance with this disclosure, novel semiconductor devices are provided herein. The semiconductor devices can comprise any type of diode (light emitting, laser, Schottky, Zener and/or rectifier diodes), integrated circuit, integrated circuit device, photocell, field-effect transistor (FET), MOSFET, monolithic microwave integrated circuits (MMIC), high-electron-mobility transistors (HEMT), sensors, switches, radio frequency (RF) device, micro-device, broadband devices, light emitting diode (LED) chips, etc.

In some aspects, semiconductor devices described herein comprise a substrate and an active area disposed over the substrate. The active area comprises at least one or more corner region having a non-orthogonal edge. Providing an active area or “mesa” having non-orthogonal angled corner regions decreases the number of failures associated with corner cracking, and provides more robust LED chips. In some aspects, the active area disposed over the substrate comprises a border (e.g., periphery) which is devoid of a 90° angle.

A method of providing a semiconductor device is also provided. The method comprises providing a substrate and fabricating an active area over the substrate, so that the active area comprises at least one or more corner region with a non-orthogonal angled edge. This method provides chips having a reduced sensitivity to corner cracking, fractures, or chips.

It is, therefore, an object of the present disclosure herein to provide improved semiconductor devices and related methods that are more robust (e.g., less sensitive) to failure due to corner fractures, breaks, or chips without sacrificing a substantial amount of active area. Another object of the present disclosure is to improve manufacturing yields associated with semiconductor devices, such as LED chips. These and other objects of the present disclosure as can become apparent from the disclosure herein are achieved, at least in whole or in part, by the subject matter disclosed herein.

### BRIEF DESCRIPTION OF THE DRAWINGS

A full and enabling disclosure of the present subject matter including the best mode thereof to one of ordinary skill in the art is set forth more particularly in the remainder of the specification, including reference to the accompanying figures, in which:

FIGS. 1A and 1B are schematic views illustrating an exemplary semiconductor device, for example, a light emitting diode (LED) chip as known in the art;

FIGS. 2A to 2E are schematic views illustrating LED chips according to the disclosure herein;

FIGS. 3A and 3B are schematic views illustrating exemplary steps of providing LED chips according to the disclosure herein;

FIGS. 4A to 4D are schematic views illustrating further embodiments of LED chips according to the disclosure herein; and

FIG. 5 is a schematic view illustrating a further embodiment of an LED chip according to the disclosure herein.

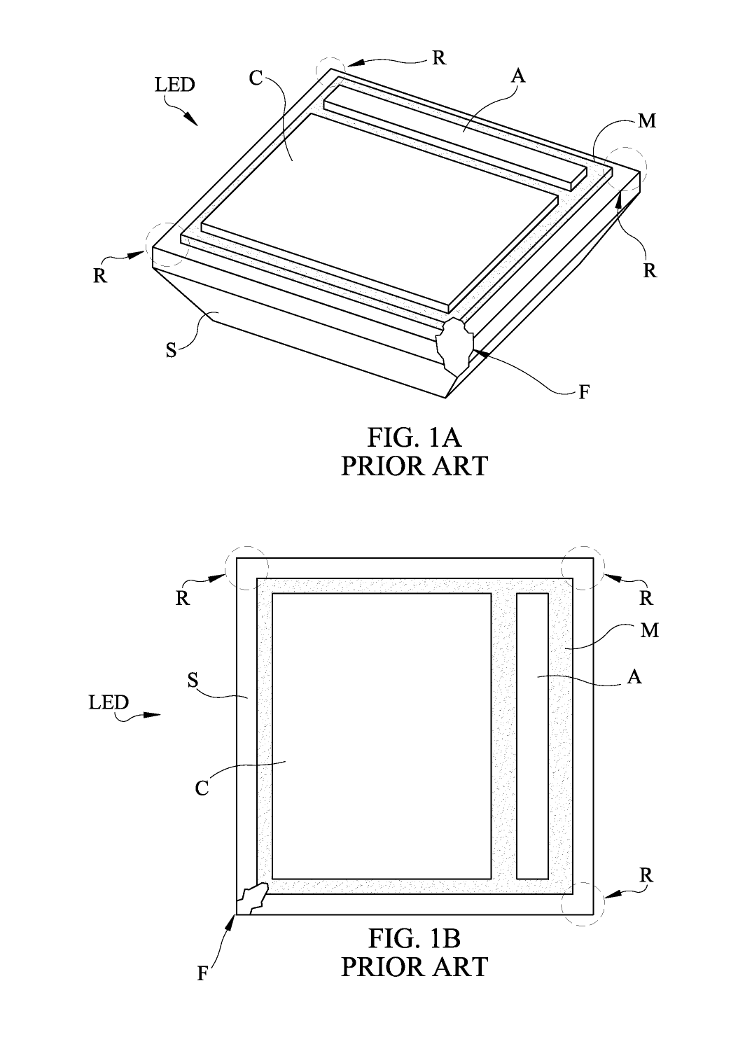

### DETAILED DESCRIPTION

In accordance with this disclosure, novel semiconductor devices and methods are provided that are well suited for a variety of different applications. As used herein, the term “semiconductor devices” denotes any type of device having a substrate and one or more layers of material fabricated on or over the substrate. Semiconductor devices can comprise any type of diode (light emitting, laser, Schottky, Zener and/or rectifier diodes), integrated circuit, integrated circuit device or component, photocell, field-effect transistor (FET), MOSFET, monolithic microwave integrated circuits (MMIC), high-electron-mobility transistors (HEMT), switches, sensors, radio frequency (RF) device, micro-device, broadband devices, light emitting diode (LED) chips, etc.

One exemplary semiconductor device is a light emitting diode (LED) chip. LED chips and related methods are provided that are well suited for a variety of general lighting applications. LED chips and related methods described herein comprise a substrate and an active area disposed over the substrate. The substrate and active area can comprise different shapes, and in some aspects, at least one or more corner region of the active area has a non-orthogonal, angled side or edge. This improves the robustness of the LED chip, and reduces the potential for failure due to cracking, chipping, or breakage at the corners of the LED chips. LED chips and methods disclosed herein are scalable up and down for use with any size and/or shape of LED chip.

As used herein, the terms “orthogonal” and “non-orthogonal” refer to a substantial or general appearance of an object at some level of magnification. In some aspects as provided herein, one or more corner regions of the active area have a non-orthogonal, angled side or edge. The term “angled” refers to a general appearance of two lateral sides which form an angle (i.e., not rounded), the lateral sides define a point or angle which is measurable (e.g., with a protractor) between approximately 0° and 180°.

Reference will now be made in detail to possible aspects or embodiments of the subject matter herein, one or more examples of which are shown in the figures. Each example is provided to explain the subject matter and not as a limitation. In fact, features illustrated or described as part of one embodiment can be used in another embodiment to yield still a further embodiment. It is intended that the subject matter disclosed and envisioned herein covers such modifications and variations.

As illustrated in the various figures, some sizes of structures or portions are exaggerated relative to other structures or portions for illustrative purposes and, thus, are provided to illustrate the general structures of the present subject matter. Furthermore, various aspects of the present subject matter are described with reference to a structure or a portion being formed on other structures, portions, or both. As will be appreciated by those of skill in the art, references to a structure being formed “on” or “above” another structure or portion contemplates that additional structure, portion, or both may intervene. References to a structure or a portion being formed “on” another structure or portion without an intervening structure or portion are described herein as being formed “directly on” the structure or portion. Similarly, it will be understood that when an element is referred to as being “connected”, “attached”, or “coupled” to another element, it can be directly connected, attached, or coupled to the other element, or intervening elements may be present. In contrast, when an element is referred to as being “directly connected”, “directly attached”, or “directly coupled” to another element, no intervening elements are present.

Furthermore, relative terms such as “on”, “above”, “upper”, “top”, “lower”, or “bottom” are used herein to describe one structure's or portion's relationship to another structure or portion as illustrated in the figures. It will be understood that relative terms such as “on”, “above”, “upper”, “top”, “lower” or “bottom” are intended to encompass different orientations of the chip or device in addition to the orientation depicted in the figures. For example, if the chip or device in the figures is turned over, structure or portion described as “above” other structures or portions would now be oriented “below” the other structures or portions. Likewise, if chips or devices in the figures are rotated along an axis, structure or portion described as “above”, other structures or portions would now be oriented “next to” or “left of” the other structures or portions. Like numbers refer to like elements throughout.

Solid state light emitters according to embodiments of the subject matter described herein can comprise group III-V nitride (e.g., gallium nitride) based LED chips or lasers fabricated on a growth substrate (with or without a carrier substrate), for example, a silicon carbide substrate, such as the devices manufactured and sold by Cree, Inc. of Durham, N.C.

Solid state light emitters, such as LED chips, can also be fabricated on sapphire growth substrates. In some aspects, Silicon Carbide (SiC) substrates described herein can be 4H polytype silicon carbide substrates or layers. Other silicon carbide candidate polytypes, such as 3C, 6H, and 15R polytypes, however, may be used. Appropriate SiC substrates are available from Cree, Inc., of Durham, N.C., the applicant and assignee of the present subject matter, and the methods for producing such substrates are set forth in the scientific literature as well as in a number of commonly assigned U.S. patents, including but not limited to U.S. Pat. No. Re. 34,861; U.S. Pat. No. 4,946,547; and U.S. Pat. No. 5,200,022, the disclosures of which are incorporated by reference herein in their entireties. Any other suitable growth substrates are contemplated herein. For example, sapphire and gallium arsenide (GaAs) can be utilized as growth substrates for fabricating LED chips or lasers as described herein.

As used herein, the term “Group III nitride” refers to those semiconducting compounds formed between nitrogen and one or more elements in Group III of the periodic table, usually aluminum (Al), gallium (Ga), and indium (In). The term also refers to binary, ternary, and quaternary compounds such as gallium nitride (GaN), AlGaN and AlInGaN. The Group III elements can combine with nitrogen to form binary (e.g., GaN), ternary (e.g., AlGaN), and quaternary (e.g., AlInGaN) compounds. These compounds may have empirical formulas in which one mole of nitrogen is combined with a total of one mole of the Group III elements. Accordingly, formulas such as AlxGa1-xN where 1>x>0 are often used to describe these compounds. Techniques for epitaxial growth of Group III nitrides have become reasonably well developed and reported in scientific literature.

Although various embodiments of LED chips disclosed herein comprise a growth substrate, it will be understood by those skilled in the art that the crystalline epitaxial growth substrate on which the epitaxial layers comprising an LED are grown may be removed, and the freestanding epitaxial layers may be mounted on a substitute carrier substrate or substrate which may have different thermal, electrical, structural and/or optical characteristics than the original substrate. The subject matter described herein is not limited to structures having crystalline epitaxial growth substrates and may be used in connection with structures in which the epitaxial layers have been removed from their original growth substrates and bonded to substitute carrier substrates.

LED chips according to some embodiments of the present subject matter can be fabricated on growth substrates to provide horizontal devices (i.e., having both electrical contacts on a same side of the LED) or vertical devices (i.e., having electrical contacts of opposing electrical polarity on opposing sides of the substrate). The growth substrate may be maintained on the LED after fabrication or removed (e.g., by etching, grinding, polishing, etc.). The growth substrate may be removed, for example, to reduce a thickness of the resulting LED and/or to reduce a forward voltage through a vertical LED.

A horizontal device (e.g., with or without the growth substrate), for example, may be flip chip bonded (e.g., using, for example, adhesive, epoxy, or solder) to a carrier substrate or printed circuit board (PCB), or wire bonded. A vertical device (e.g., with or without the growth substrate) may have a first terminal solder bonded to a carrier substrate, mounting pad, or PCB and a second terminal wire bonded to the carrier substrate, electrical element, or PCB. Examples of vertical and horizontal LED chip structures are discussed by way of example in U.S. Publication No. 2008/0258130 to Bergmann et al. and in U.S. Publication No. 2006/0186418 to Edmond et al., the disclosures of which are hereby incorporated by reference herein in their entireties.

Electrically activated LED chips, can be used individually or in groups to emit one or more beams to stimulate emissions of one or more lumiphoric materials (e.g., phosphors, scintillators, lumiphoric inks, quantum dots) to generate light at one or more peak wavelengths, or of at least one desired perceived color (including combinations of colors that can be perceived as white). Combining lumiphoric (also called ‘luminescent’) materials with chips as described herein can be accomplished by an application of a direct coating of the material on lumiphor support elements or lumiphor support surfaces (e.g., by powder coating, inkjet printing, or the like), adding such materials to packaged LED structures (e.g., lenses), and/or by embedding or dispersing such materials within lumiphor support elements or surfaces. Methods for fabricating LED chips having a planarized coating of phosphor integrated therewith are discussed by way of example in U.S. Patent Application Publication No. 2008/0179611 to Chitnis et al., the disclosure of which is hereby incorporated by reference herein in the entirety.

Other materials, such as light scattering elements (e.g., particles) and/or index matching materials can be associated with a lumiphoric material-containing element or surface. LED chips and related methods as disclosed herein can comprise LED chips adapted to emit different colors, of light one or more of which can be white emitting (e.g., including at least one LED chip with one or more lumiphoric materials).

In some aspects, one or more short wavelength solid state emitters (e.g., blue and/or cyan LED chips) can be used to stimulate emissions from a mixture of lumiphoric materials, or discrete layers of lumiphoric material, including red, yellow, and green lumiphoric materials. LED chips of different wavelengths can be present in a group of solid state emitters. A wide variety of wavelength conversion materials (e.g., luminescent materials, also known as lumiphors or lumiphoric media, e.g., as disclosed in U.S. Pat. No. 6,600,175 and U.S. Patent Application Publication No. 2009/0184616), are well-known and available to persons of skill in the art.

As described, one or more LED chips can be coated, at least partially, with one or more phosphors with the phosphors absorbing at least a portion of the LED light and emitting a different wavelength of light such that the LED emits a combination of light from the LED and the phosphor. In one embodiment, the LED emits a white light which is a combination of light emission from the LED chip and phosphor. One or more LED chips can be coated and fabricated using many different methods, with one suitable method being described in U.S. patent application Ser. Nos. 11/656,759 and 11/899,790, both entitled “Wafer Level Phosphor Coating Method and Devices Fabricated Utilizing Method”, and both of which are incorporated herein by reference in their entireties.

Other suitable methods for coating one or more LED chips are described in U.S. patent application Ser. No. 12/014,404 entitled “Phosphor Coating Systems and Methods for Light Emitting Structures and Packaged Light Emitting Diodes Including Phosphor Coating” and the continuation-in-part application U.S. patent application Ser. No. 12/717,048 entitled “Systems and Methods for Application of Optical Materials to Optical Elements”, the disclosures of which are hereby incorporated by reference herein in their entireties. LED chips can also be coated using other methods such electrophoretic deposition (EPD), with a suitable EPD method described in U.S. patent application Ser. No. 11/473,089 entitled “Close Loop Electrophoretic Deposition of Semiconductor Devices”, which is also incorporated herein by reference in its entirety. It is understood that LED chips and methods according to the present subject matter can also include provision of multiple LED chips of different colors, one or more of which may be white emitting. LED chips emitting white light and/or any other color(s) or color point(s) are also contemplated herein.

LED chips described herein can comprise any suitable device available from Cree, Inc., of Durham, N.C., the assignee of the present subject matter, and any methods for producing such chips as set forth in commonly assigned U.S. patents, including but not limited to U.S. Pat. No. 6,515,313; U.S. Pat. No. 7,211,833; U.S. Pat. No. 7,312,474; U.S. Pat. No. 7,446,345; U.S. Pat. No. 7,473,938; U.S. Pat. No. 7,692,182; and U.S. Pat. No. 7,692,209, the disclosures of which are incorporated by reference herein in their entireties.

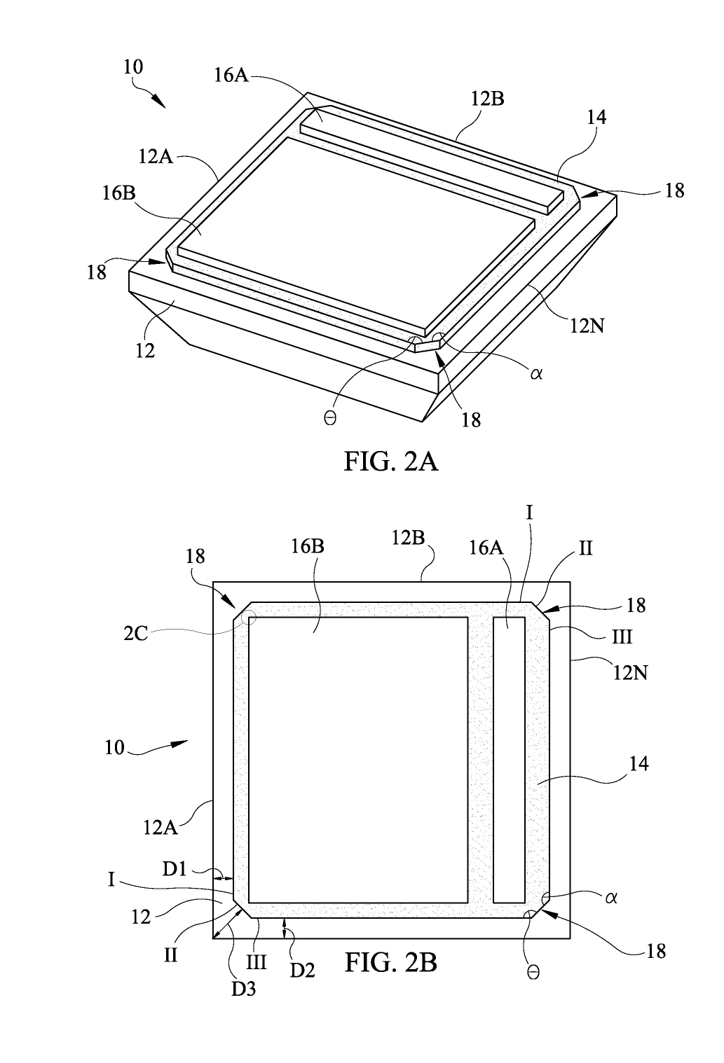

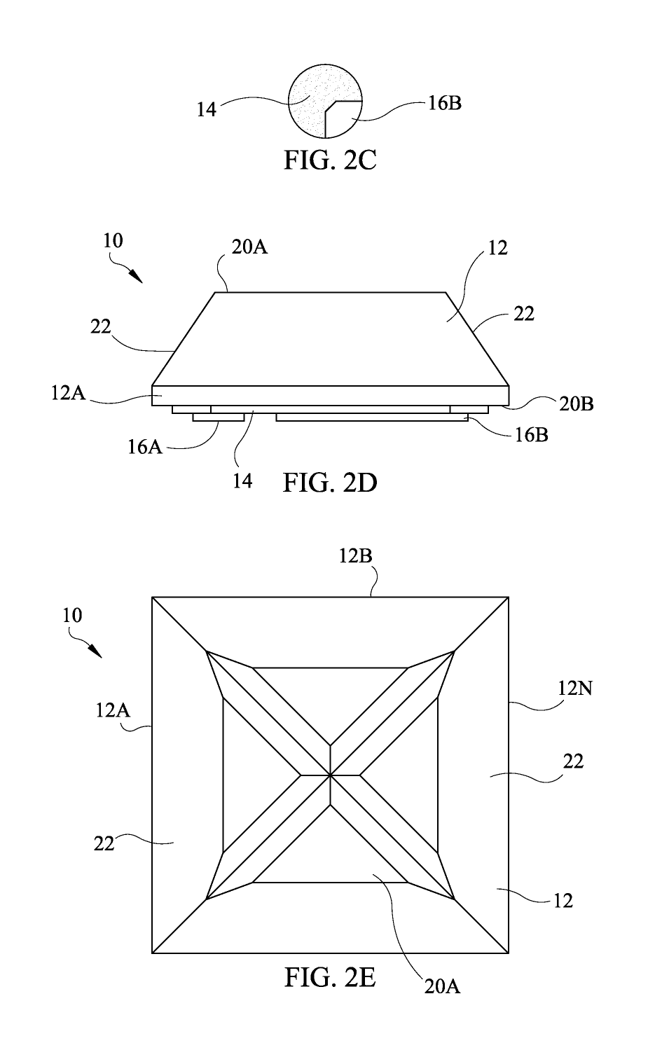

Referring now to FIGS. 2A to 5, novel LED chips and related methods are illustrated, disclosed, and described. In some aspects, novel LED chips and related methods described herein provide improve chips, which are more insensitive to chipping, breaking, and/or fracturing in some aspects proximate the outermost (e.g., peripheral) corners of the chip or chip substrate. The improved LED chips and related methods described herein are energy efficient, bright, and have improved yields, while avoiding many of the disadvantages (e.g., chips that are likely to fail and/or that are otherwise susceptible to corner chipping) associated with conventional designs.

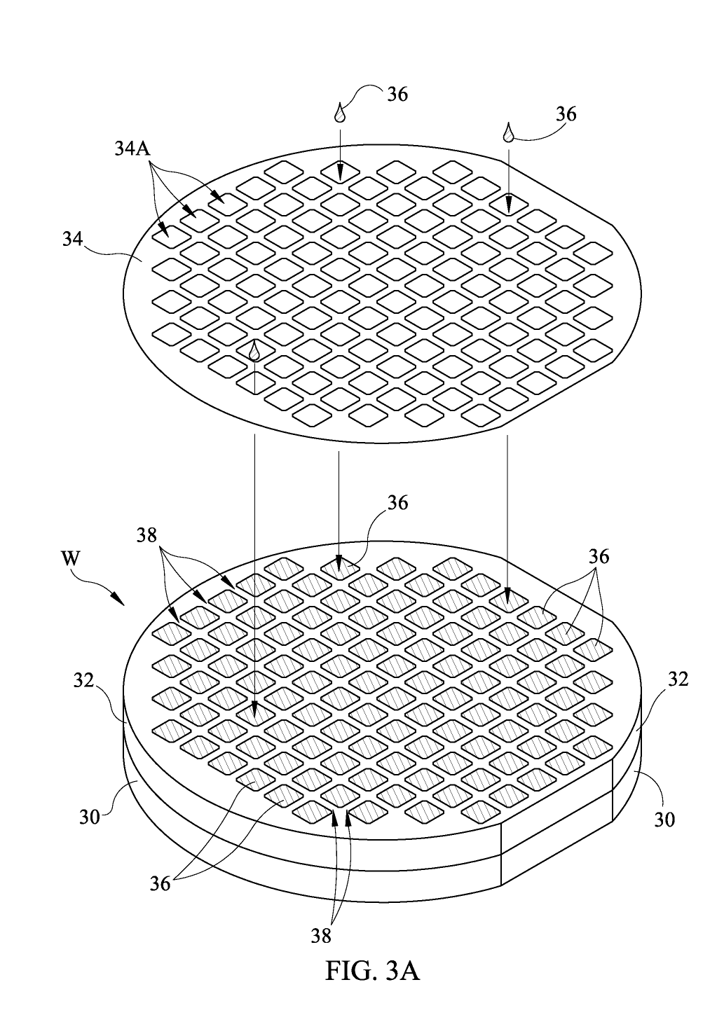

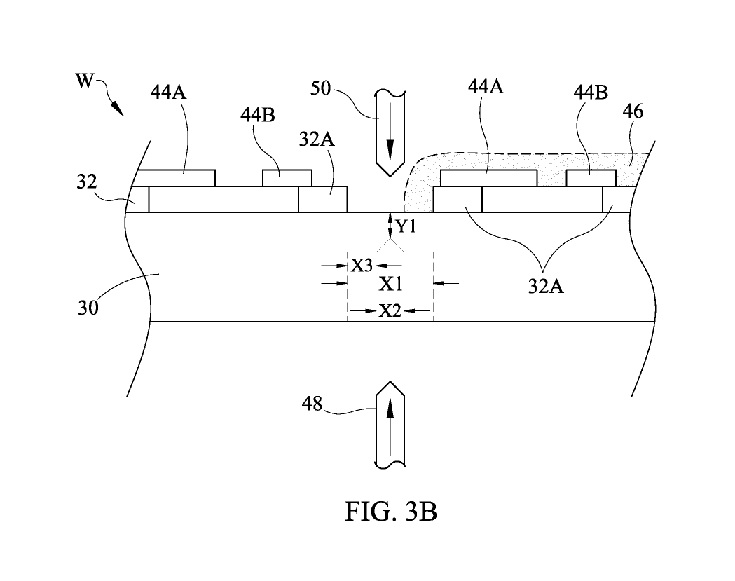

Referring now to FIGS. 2A to 2E, an exemplary embodiment of an improved solid state light emitter or LED chip, generally designated 10, is illustrated according to aspects of the disclosure. In some aspects, LED chip 10 comprises a substrate 12 for supporting one or more additional layers of material (e.g., epitaxial layers and/or metallic layers) thereon. Substrate 12 can comprise a chip body provided from any suitable growth or carrier substrate material, not limited to Si, SiC, silicon on insulator (SOI), sapphire, GaAs, GaN, AlN, Al₂O₃, LiAlO₂, ZrB₂, MgO, Germanium (Ge), Indium Phosphide, combinations thereof, and/or any other suitable material. In some aspects, a plurality of individual LED chips (e.g., chips 10) having individual substrates 12 can be singulated from a single wafer (see e.g., FIGS. 3A and 3B).

Substrate 10 can comprise one or more lateral sides or edges, generally designated 12A to 12N (where “N” is a whole number integer >2), which can be approximately equal in length and width, or vary in length and width, and therefore be configured to form different sizes and/or shapes. Substrate 12 can comprise any suitable size and/or shape, for example, a square, a rectangle, a triangle, a regular shape, an irregular shape, a symmetric shape, a non-symmetric shape, and/or any non-square and/or non-rectangular shape, where desired.

Substrate 12 can also comprise any suitable size, for example, having at least one edge 12A that is: greater than or approximately equal to 200 micrometers (μm); greater than or approximately equal to 300 μm; greater than or approximately equal to 500 μm; greater than or approximately equal to 700 μm; and/or greater than or approximately equal to 1000 μm. Substrate 12 can comprise all sides or edges (e.g., 12A to 12D) of a same (e.g., equal) length or dimension and/or edges (e.g., 12A to 12D) of different lengths and/or different dimensions. LED chip 10 can comprise any size, shape, dimension, structure (i.e., horizontal or vertical build), and/or substrate 12 material, where desired.

Referring in general to FIGS. 2A to 2D, LED chip 10 can also comprise any desired electrical or optical properties as specified by a lighting device end-user, designer, and/or manufacturer. In some aspects, a plurality of LED chips 10 are binned or grouped based upon optical properties, such as e.g., brightness, wavelength, and/or both. LED chip 10 can be adapted to emit light that is primarily red, green, cyan, amber, yellow, orange, blue and/or any wavelengths corresponding thereto (i.e., any wavelength or range of wavelengths in the spectrum such as infrared light, ultraviolet (UV) light, and/or wavelengths in the visible spectrum).

In some aspects, LED chip 10 is adapted to emit light that is approximately 6 milliwatts (mW) or more, approximately 10 mW or more, approximately 21 mW or more, or approximately 27 mW or more as measured at a forward current of approximately 20 milliamps (mA). In other aspects, LED chip 10 is adapted to emit approximately 110 mW or more, approximately 200 mW or more, approximately 400 mW or more, or approximately 460 mW or more, approximately 500 mW or more, approximately 560 mW or more, or approximately 625 mW or more, as measured at a forward current of approximately 350 mA.

Referring to FIGS. 2A to 2E, LED chip 10 can further comprise an active area or mesa, generally designated 14. As used herein, the term “mesa” refers to the illuminating portion of the LED chip, which illuminates upon activation or excitement by electrical current or signal. Mesa 14 is the junction area comprised of the p- and n-layers of material (i.e., a PN junction). Mesa 14 is shown as one (e.g., illuminating) layer for illustration purposes. However, in actuality, mesa 14 can comprise a plurality of layers. In some aspects, mesa 14 is not a same shape as substrate 12, for example, proximate the outermost or peripheral corners of substrate 12 so that chipping at the corners of substrate 12 does not and/or is less likely to affect mesa 14, and the light emitted thereby. Thus, mesa 14 can comprise shaped or patterned corner regions (e.g., which are non-orthogonal) to minimize the effects of corner chipping, and to improve LED chip manufacturing yields.

In some aspects, electrical current passes into and/or through mesa 14 and chip 10 via electrical contacts 16A and 16B. Electrical contacts 16A and 16B can comprise anode and cathode terminals by which current or electrical signal enters into and illuminates LED chip 10 via excitation of electrons and holes in mesa 14 and/or layers thereof. Electrical contacts 16A and 16B can comprise an electrically conductive material (e.g., a metal or metal alloy) and can be patterned or formed over portions of mesa 14 via physical, chemical, and/or plasma deposition, plating, sputtering, stenciling, and/or any other suitable process. Contacts 16A and 16B can comprise contacts of any suitable material, such as Au, Ag, Cu, Ti, Ni, Sn, Pt, Indium Tin Oxide (ITO), any other transparent conducting oxides, and/or any alloys or combinations thereof. Contacts 16A and 16B can comprise surface mount pads configured to electrically and physically connect to a circuit carrying substrate (e.g., PCB, MCPCB, etc.) or bond pads configured to physically and electrically connect with another device or component via wires or wire-bonding (not shown).

For illustration purposes, a horizontal LED chip 10 is illustrated, in which contacts of opposing electrical polarity 16A and 16B are disposed on a same side or surface of mesa 14 and/or chip 10. However, vertical LED chips 10 having contacts 16A and 16B on different sides of chip 10 and mesa 14 can also be provided, where the different sides are not limited to opposing faces or sides of LED chip 10 and mesa 14.

As noted above and in aspects, mesa 14 can comprise a different shape than substrate 12. Lateral side (e.g., perimeter) edges, a surface area, and/or a shape of mesa 14 can be patterned or formed into any non-square, non-rectangular, circular, non-circular, regular, non-regular, symmetric, and/or non-symmetric shape via photomasking, stenciling, etching, cutting, and/or laser scribing process. In some aspects, mesa 14 can comprise non-orthogonal corner regions or areas (e.g., outermost corner regions or areas), generally designated 18. In some aspects, conventional right angled (e.g., 90 degrees (°), pointed) portions of at least one corner region 18 are removed (e.g., via etching, photomasking, scribing, stenciling, etc.), which accounts for removal of approximately 1% or less of the entire surface area of mesa 14. Corners regions 18 can comprise areas and corresponding edges that are contoured, chamfered, curved, and/or any other non-90° configuration, where desired, for providing LED chips 10 that are desensitized with respect to corner fractures or chips.

Decreasing the size of mesa 14 and/or providing a different shape of mesa 14 compared to substrate 12 (e.g., by removing sharp corners) is unexpected and provides unexpected results, as typically a reduction in the surface area of mesa 14 corresponds to and/or results in a reduction in light output, extraction, or brightness at a given current. However, LED chips 10 herein fail to exhibit a reduction in light extraction and/or any other negative effects in regards to light output. As the bulk of the electrical current passes through and is, therefore, emitted by a central portion of mesa 14, forming or shaping corners to have non-orthogonal edges (e.g., touching or intersecting edges) does not negatively affect light output. Removing one or more sharp, right angled corner portion(s) of mesa 14, moves the borders of mesa 14 inboard of substrate 12 edges or corners, which are the most sensitive to and/or susceptible to cracking, fracturing, or chipping. In some aspects, the outer border or perimeter edges of mesa 14 can be devoid of a right angle.

In some aspects, the amount of substrate 12 material provided proximate at least one corner region or portion of chip 10 is increased in the novel LED chip structure and design set forth herein. Each corner region 18 need not be shaped differently than substrate 12, as in some aspects only one corner region 18 is shaped differently than substrate 12, only two corner regions 18 are shaped differently than substrate 12, or less than each corner region 18 is shaped differently. Some portions of substrate 12 may be more susceptible to cleaving, chipping, and/or fracturing, thus, all corner regions 18 may not require shaping. However, as FIG. 2A illustrates and in some aspects, each corner region 18 can be shaped.

As FIGS. 2A and 2B further illustrate, the amount of substrate 12 material proximate corner portions of chip 10 is increased during fabrication of chips 10, as mesa 14 is etched or shaped using a different mask size and/or mask shape (e.g., FIG. 3A). In some aspects, an amount of substrate 12 disposed outside of mesa 14 along a first side is represented by a distance D1 and an amount of substrate 12 disposed outside mesa 14 on a second, different and/or adjacent side is represented by a second distance D2. First and second D1 and D2 can be approximately equal or unequal. First and second distances D1 and D2, respectively, can be for example: approximately 10 μm or more; approximately 20 μm or more; approximately 30 μm or more; or approximately 40 μm or more. In some aspects, an amount of substrate 12 disposed outside of corner portions 18 of mesa 14 is represented by a third distance D3. Notably, third distance D3 is greater than (e.g., longer, wider, or thicker than) first and second distances D1 and D2, such as for example and without limitation by more than about 140%, for example, by at least approximately 150% or more, or by at least approximately 200% or more; by at least approximately 300% or more; by at least approximately 400% or more; or more than 500% each by +/−10%. That is, third distance D3 is greater than (e.g., longer, wider, or thicker than) first and second distances D1 and D2, by at least approximately three times or more; by at least approximately three and a half (3.5) times or more; by at least approximately four times or more; by at least approximately five times or more; or approximately six times or more.

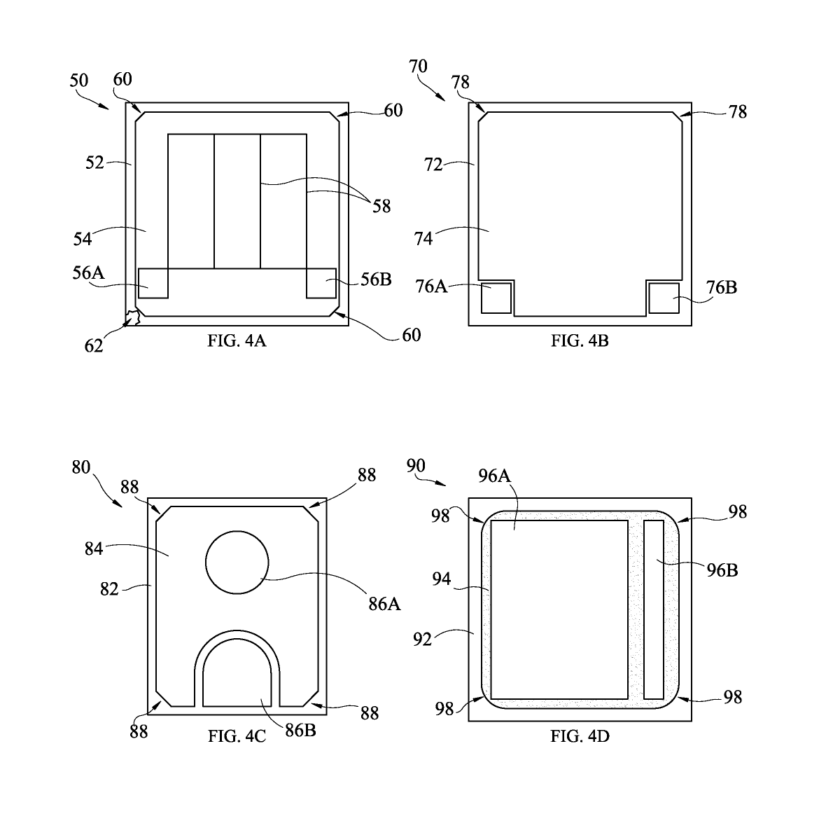

As FIGS. 2A and 2B further illustrate, at least one corner region 18 of mesa 14 comprises one or more angles, generally designated θ and α, that are greater than 90°. In some aspects, each corner region 18 comprises at least two angles θ and α that are obtuse and greater than 90°. Angles θ and α can comprise the same degree (e.g., equal) or angle and/or different degrees (e.g., not equal) or angles. In some aspects, corner regions 18 comprise more than two edges or sides, designated I, II, and III. Corner regions 18 do not have to be angled, but may be rounded or curved (FIG. 4D). Corner regions 18 can be shaped via angling, beveling, chamfering, and/or rounding using any desired tool, mask, or process. The shape of corner regions 18 may be defined via etching or removing portions of a mesa 14 via a photomask (e.g., 34, FIG. 3A) during wafer fabrication. Corner regions 18 can be devoid of a right angle (e.g., 90° angle), thus devoid of orthogonal edges.

In some aspects, LED chip 10 comprises a semiconductor device in which mesa 14 has a greater number of linear lateral sides or side edges than substrate 12. For example, substrate 12 can comprise four substantially linear sides or side edges (e.g., 12A, 12B, etc.). Mesa 14 can comprise an outer or peripheral border having more than four linear side edges. For example, as FIG. 2B illustrates, mesa 14 can comprise at least five linear side edges, at least six linear side edges, at least seven linear side edges, or at least eight linear side edges. Obtuse angles are provided between each linear side of mesa 14, in some aspects. Mesa 14 can comprise any number of linear sides forming non-orthogonal angles. FIG. 2C is an exploded view of a portion of LED chip 10. As FIG. 2C illustrates, portions of electrical contacts 16A and/or 16B can be optionally chamfered or shaped as needed, to accommodate chamfering of active layer. At least one corner of electrical contacts 16A and 16B can be chamfered or shaped, or each corner of electrical contacts 16A and 16B can be chamfered or shaped, where desired and/or necessary.

As FIGS. 2D and 2E illustrate and in some aspects, LED chip 10 comprises sides or edges 12A to 12D, portions of which extend between an upper surface 20A and a lower surface 20B of substrate 12. In some aspects, LED chip 10 comprises outermost edges or sides 22 that are beveled (i.e., bevel-cut or substantially angled between upper and lower surfaces of substrate 12) and/or straight-cut (i.e., substantially vertical between upper and lower surfaces). LED chip 10 can comprise a substrate 12 having a patterned upper surface 20A, such as an X- or V-shaped grooves formed thereon for increasing brightness, reflection, and/or light extraction.

Referring now to FIGS. 3A and 3B, methods of providing LED chips (e.g., 10) according to the disclosure herein are illustrated. FIG. 3A illustrates a step occurring during a wafer fabrication process. As FIG. 3A illustrates, a wafer W is provided. Wafer W comprises a uniform substrate 30 over which an active region, junction, or mesa layer 32 is provided. Substrate 30 can comprise a growth or carrier substrate and any suitable material (e.g., Si, SiC, GaAs, etc.) as described above. Mesa layer 32 can comprise a junction of a plurality of epitaxial layers and/or materials (e.g., p-type and n-type layers and materials), which are configured to illuminate upon passage of electrical current there through. A plurality of individual devices (e.g., individual chips, 10) can be singulated from wafer W during a manufacturing process.

As FIG. 3A further illustrates and in some aspects, a photomask 34 can be provided over wafer W. Photomask 34 can comprise a plurality of openings 34A, through which a photoresist 36 or photoresist material is applied. Photoresist 36 can be stenciled or otherwise applied over portions of mesa layer 32 via photomask 34, to portions of mesa layer 32 which are not to be etched. That is, areas not covered with photoresist 36 will become etched, or otherwise removed, via a chemical, laser, or etchant. A plurality of intersecting substrate “streets”, generally designated 38, which are not covered with photoresist 36, can become etched in some aspects down to the substrate 30 layer. Mesa layer 32 that is uncovered and disposed within streets 38 becomes etched or otherwise removed and can comprise a layer of substrate material 30, which is later sawn or broken for singulation LED chips (e.g., FIG. 3B).

In some aspects, streets 38 disposed on substrate 30 are susceptible to chipping, cracking, fracturing, breaking, etc., especially at the corners, or intersections of streets 38. However, any negative effects from such damage is minimized or mitigated by shaping corners of mesa layer 32 (e.g., the PN junction layer) to remove sharp corners from mesa layer 32 and/or to locate the corners of mesa layer 32 inboard of what will become LED chip corners via photomask 34. In some aspects, photomask 34 is used to form, pattern, or stencil a plurality of mesas (e.g., 14, FIG. 2A) having non-orthogonal (e.g., angled or chamfered) corner regions over substrate 30. Substrate 30 can comprise a growth or carrier substrate (e.g., a secondary substrate that is applied after the growth substrate is removed) as described above.

Notably, individually patterning of LED chip mesas (e.g., rounding, chamfering, or reducing corner) over a wafer substrate, which reduces the failure and/or the potential for failure due to corner breakage, fracturing, or chipping of individual LED chips (e.g., 10, FIG. 2A) can be provided with minimal interruption to wafer fabrication and/or LED chip manufacturing processes. Thus, methods of providing improved LED chips as described herein can advantageously become easily implemented within existing manufacturing processes.

FIG. 3B illustrates an LED chip singulation process, in which individual chips are separated or singulated from wafer W. FIG. 3B illustrates wafer W comprised at least of substrate 30 (e.g., carrier or growth) and mesa layer 32, or PN junction layer. For ease of processing, wafer W is provided over an adhesive carrying substrate (not shown), such as a layer of tape, or any other adhesive materiel, to which wafer W can be secured, carried, and transferred during different processing steps. After the singulation step illustrated in FIG. 3B, the carrying structure (not shown) can be stretched for separating adjacent, singulated LED chips. This allows the chips to be individually probed (e.g., optically tested) and binned based upon individual optical properties using, for example, pick-and-place machinery.

FIG. 3B illustrates wafer W having an additional layer of material fabricated over mesa layer 32. For example, electrical terminal or contacts 44A and 44B are provided over each mesa layer 32 portion. Electrical current can enter and illuminate mesa layer 32 by passing through contacts 44A and 44B. Electrical contacts can be formed on a same side or different sides of mesa layer 32 (e.g., PN junction) and/or substrate 30 for providing horizontally or vertically structured LED chips.

Corners of junction or mesa layer 32 are configured, such as by being chamfered or obtusely angled, proximate corner regions 32A to minimize the risk of becoming damaged due to cracking or fracturing of LED chips, for example, by the mere handling of the LED chips during manufacturing processes. As FIG. 3B illustrates and in some aspects, wafer W can be coated with a planarized layer of optical conversion material 46 prior to singulation. Optical conversion material 46 is indicated in broken lines, as it is optional, but in some aspects, conversion material 46 can be applied and disposed over the entire wafer W during wafer fabrication. Optical conversion material 46 can comprise any suitable material such as, for example, any phosphor containing material or lumiphoric material adapted to emit light upon impingement of light from mesa layer 32.

Wafer W can be separated into a plurality of individual LED chips via sawing and/or optional breaking process steps. As FIG. 3B illustrates, a saw (e.g., a mechanical, chemical, or laser saw) 48 is adapted to cut through a portion of streets 38. Saw 48 can comprise a blade or a laser cutting tool, and any type of saw 48 is contemplated. The streets 38 are disposed between portions of mesa layer 32 (e.g., which were not etched or removed by virtue of coverage or provision with photoresist 36, FIG. 3A). Streets 38 can be any suitable thickness or width X1, for example, 25 μm or more, 30 μm or more, 40 μm or more, or 50 μm or more.

In some aspects, saw 48 (e.g., comprised of a blade or laser) is configured to cut into streets 38 and substrate 30 and provide a cut having about a same size thickness or width X2 as the saw blade or laser thickness. The saw cut is indicated in broken lines within substrate 30. A blade width or laser saw thickness X2 can for example be approximately 5 μm or more, approximately 10 μm or more or approximately 25 μm or more. Any suitable street 38 and saw blade X2 dimensions (e.g., X1 and X2) are contemplated. In some aspects, saw 48 may not fully extend or cut entirely through wafer W thickness. Rather, an amount of substrate 30 material may remain uncut, having a thickness or length, designated Y1.

After cutting, dicing, or sawing through portions of streets 38 formed by substrate 30, an amount of material remaining outside of mesa layer 32 is designated X3. Depending upon the type of LED chip, the amount of material remaining outside of mesa layer X3 can be approximately 10 μm or more, 20 μm or more, or 30 μm or more.

After dicing via saw 48, wafer W can optionally be subjected to a breaking process or step. During the breaking step, a breaking tool 50 can be applied to an opposing of wafer W, for breaking substrate 30 along Y1. Thus, the amount of uncut material (e.g., of a thickness Y1) can be broken or cleaved via tool 50 to ultimately singulate wafer W into a plurality of LED chips. Should cracking or chipping occur at corners of the diced and/or broken substrate 30, such damage is minimized as corners of mesa layer 32 were shaped, patterned, chamfered, or obtusely angled during fabrication. Sawing and breaking can occur on a same side or different sides of substrate 30.

FIG. 4A to 4D illustrate exemplary plan views of LED chip having uniquely shaped junction or mesa layers or areas as provided herein. Referring to FIG. 4A, a first surface (e.g., a mesa or PN junction side up surface) of an LED chip, generally designated 50 is illustrated. LED chip 50 comprises a substrate 52, a mesa layer 54 disposed over the substrate, and at least two electrical terminals or contacts, 56A and 56B for passing current into mesa layer 54. Contacts 56A and 56B can comprise electrically conductive pads adapted to pass current through chip 50 via wires and/or wire-bonding (not shown). LED chip 50 is vertically structured having a backside ohmic contact or backside metallization (not shown). Contacts 56A and 56B can comprise a same electrical polarity, such that current passes vertically through chip 50.

In some aspects, mesa layer 54 comprises a PN junction layer (e.g., comprising InGaN materials) adapted to illuminate and emit light upon excitation via introduction of electrical current. LED chip 50 can comprise a current spreading structure 58 disposed between contacts 56A and 56B for more readily dissipating current, heat, and reducing hot spots within LED chip 50.

As FIG. 4A illustrates, at least one corner region 60 of mesa 54 is angled, chamfered, beveled, and/or spaced further inboard from edges of substrate 52 than other, adjacent edges of mesa 54. In some aspects corner regions 60 are comprised of non-orthogonal, obtusely disposed, and/or curved edges. Mesa 54 can be devoid of right angled corners, which can prevent damage to mesa 54, should a crack or chip occur in a corner of LED chip 50.

For example, FIG. 4A illustrates a crack, chip, or fracture, generally designated 62. By moving corner regions 60 of mesa 54 inboard from the corner or corner edges of LED chip 50, the potential for damaging mesa 54 is greatly reduced. That is, corner crack or chip 62 is less likely to touch, extend into, and/or damage mesa 54. Thus, LED chip 50 yields improve by reducing the amount of leaky and/or dark chips, and light output is not negatively affected as the majority of light is emitted from portions of mesa 54 other than peripheral edges. In some aspects, each corner region 60 can be shaped (e.g., chamfered or obtusely angled), and in other aspects only one or two corner regions 60 can be shaped.

Referring to FIG. 4B, a first surface (e.g., a junction side up surface) of another exemplary LED chip, generally designated 70 is illustrated. LED chip 70 can comprise a substrate 72 and an active layer or mesa 74 (e.g., PN junction layer) disposed over the substrate, and at least two electrical terminals or contacts, 76A and 76B for passing current into and illuminating mesa layer 74. Contacts 76A and 76B can comprise electrically conductive pads adapted to pass current through chip 70 via wires and/or wire-bonding (not shown). LED chip 70 is vertically structured having a backside ohmic contact or backside metallization (not shown). Contacts 76A and 76B can comprise a same electrical polarity, such that current passes vertically through chip 70. As FIG. 4B, illustrates, not all corners of active area 74 are shaped differently than the underlying substrate. However, at least one peripheral corner of the active area 74 is a different shape than at least one corresponding peripheral corner of the substrate. The term “corresponding” as used herein refers to corners that are disposed in the same proximate location or region and/or along the same sides/portions of the chip.

As FIG. 4B illustrates, at least one corner region 78 of mesa 74 is obtusely angled, chamfered, beveled, and/or spaced further inboard from the corner of substrate 72 than other edges of mesa 74. In some aspects, corner regions 78 are comprised of non-orthogonal and/or obtusely angled edges. In some aspects, mesa 74 comprises a different number (e.g., more or less) of lateral sides or side edges than substrate 72. Pattering, shaping, angling, or chamfering one or more corners of mesa 74 can prevent damage to mesa 74, should a crack or chip occur in a corner of LED chip 70 (e.g., see corner fracture 62, FIG. 4A). As FIG. 4B illustrates, in some aspects, only two corner regions 78 are shaped. LED chip 70 may be packaged for use in general illumination applications, not limited to lamps, bulbs, and automotive applications.

Referring to FIG. 4C, a first surface (e.g., a junction side up surface) of another exemplary LED chip, generally designated 80 is illustrated. LED chip 80 can comprise a substrate 82 and a mesa 84 disposed over the substrate. Mesa 84 is configured to illuminate upon passage of current there through. LED chip 80 can further comprise at least two electrical terminals or contacts, 86A and 86B for passing current into and illuminating mesa layer 84. Contacts 86A and 86B can comprise electrically conductive pads of opposing polarity adapted to pass current horizontally through chip 80 via wires and/or wire-bonding (not shown). LED chip 80 is horizontally structured such that the InGaN junction layer or mesa 84 is disposed over a thermally conductive SiC substrate 82. LED chip 80 can be used in sideview packages as it is die attachable, in some aspects, via clear epoxy and has two topside contacts of opposing electrical polarity.

As FIG. 4C illustrates, at least one corner region 88 of mesa 84 can be configured such as by being chamfered, such that an amount of substrate material 82 proximate at least one corner of LED chip 80 is greater (e.g., wider, more substantial) than the amount of exposed substrate material 82 along lateral side edges. Corner regions 88 can comprise non-right angled (i.e., non-orthogonal) edges which are chamfered and have one or more obtuse angles. This improves LED chip yields and further prevents shipment or passage of leaky die to end-users, which can ultimately short out or fail.

Referring to FIG. 4D, a first surface (e.g., a junction side up surface) of another exemplary LED chip, generally designated 90 is illustrated. LED chip 90 can comprise a substrate 92 and a mesa 94 disposed over the substrate. Mesa 94 is configured to illuminate upon passage of current there through. LED chip 90 can further comprise at least two electrical terminals or contacts, 96A and 96B for passing current into and illuminating mesa layer 94. Contacts 96A and 96B can comprise electrically conductive surface mount pads of opposing polarity adapted to pass current through chip 90 when soldered or otherwise connected to a current carrier (e.g., solder pads of PCB, MCPCB). LED chip 90 is horizontally structured such that the InGaN junction or mesa 94 is mounted junction side down for improved thermal management. In some aspects, no wirebonds are required for electrically connecting LED chip 90 within a circuit. Thus, LED chip 90 can be directly attached and/or flip chip bonded to an electrical current carrier.

As FIG. 4D illustrates, corner regions 98 of mesa 94 can comprise rounded or curved edges, as opposed to angled (e.g., obtuse, acute, or right) edges. Rounding corner regions 98 locates or positions mesa 94 further inboard of outermost edges of substrate 92, thereby reducing the potential for corner cracks from reaching mesa 94 and potentially causing the LED chip to fail. In some aspects, a crack, chip, or fracture of the substrate 92 can only cause, or potentially cause, LED chip 90 to fail if the crack reaches (e.g., touches) mesa 94, as mesa 94 is the active (e.g., light generating) area. Thus, LED chips and related methods herein minimize the risk of corner cracks (e.g., 62, FIG. 4A) from reaching, touching, or extending into the mesa by moving the corner of the mesa further inboard from the substrate corners, in some aspects, by chamfering or rounding portions of the mesa.

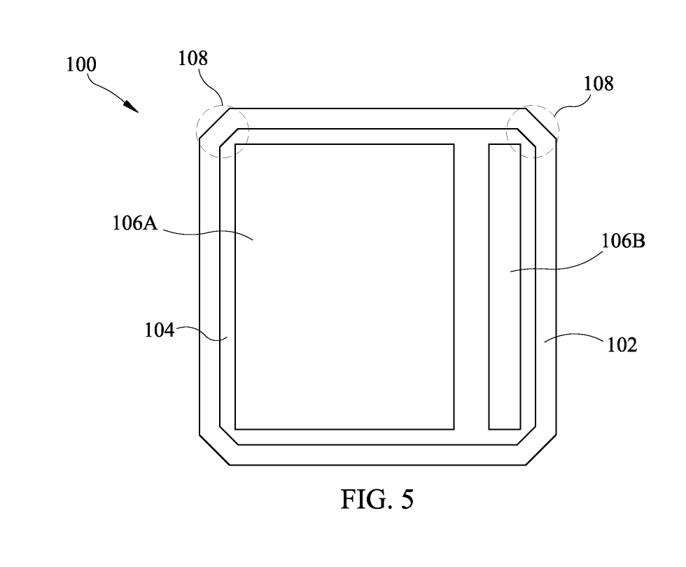

FIG. 5 is a further embodiment of an LED chip, generally designated 100, according to the disclosure herein. LED chip 100 can comprise a substrate 102 and a mesa 104. Two contacts 106A and 106B can be disposed over mesa 104 for passing electrical current there through upon providing LED chip 100 within a circuit. Notably, in some aspects both substrate 102 and mesa 104 can be patterned in a same (e.g., corresponding) shape proximate corner regions 108. In some aspects, sharp corners or edges are eliminated. This can prevent corner chips or fractures from occurring in the first place. Substrate 102 can be patterned via etchant, dicing, laser cutting, or any other suitable substrate removal process.

Aspects as disclosed herein can provide one or more of the following beneficial technical effects: reduced failure (e.g., of LED chips, packages, and/or any other lighting device or fixture incorporating one or more LED chips); reduced leakage; reduced chipping; and improved manufacturing yields.

While the subject matter has been has been described herein in reference to specific aspects, features, and illustrative embodiments, it will be appreciated that the utility of the subject matter is not thus limited, but rather extends to and encompasses numerous other variations, modifications and alternative embodiments, as will suggest themselves to those of ordinary skill in the field of the present subject matter, based on the disclosure herein.

Various combinations and sub-combinations of the structures and features described herein are contemplated and will be apparent to a skilled person having knowledge of this disclosure. Any of the various features and elements as disclosed herein can be combined with one or more other disclosed features and elements unless indicated to the contrary herein. Correspondingly, the subject matter as hereinafter claimed is intended to be broadly construed and interpreted (and not limited to LED devices or chips), as including all such variations, modifications and alternative embodiments, within its scope and including equivalents of the claims.

What is claimed is:

1. A semiconductor device comprising:
a substrate; and
an active area disposed over the substrate, wherein the active area comprises at least one or more corner region having a non-orthogonal, angled edge.

2. The semiconductor device according to claim 1, wherein the device comprises a light emitting diode (LED) chip.

3. The semiconductor device according to claim 1, wherein the device comprises a laser diode, a Schottky diode, a Zener diode, a rectifying diode, an integrated circuit, an integrated circuit device, a photocell, a field-effect transistor (FET), a metal-oxide-semiconductor field-effect transistor (MOSFET), a monolithic microwave integrated circuit (MMIC), a high-electron-mobility transistor (HEMT), a sensor, a switch, a radio frequency (RF) device, a micro-device, or a broadband device.

4. The semiconductor device according to claim 1, wherein the at least one corner region is disposed proximate an outermost corner of the substrate.

5. The semiconductor device according to claim 1, wherein at least a portion of the corner region comprises an obtuse angle.

6. The semiconductor device according to claim 1, wherein the active area comprises at least four corner regions disposed proximate at least four outermost corners of the substrate, and wherein each corner region of the active area is devoid of a 90° angle.

7. The semiconductor device according to claim 1, wherein the substrate comprises silicon (Si), Silicon Carbide (SiC), silicon on insulator (SOI), sapphire, Gallium Arsenide (GaAs), Gallium Nitride (GaN), Aluminum Nitride (AlN), alumina (Al₂O₃), Lithium Aluminate (LiAlO₂), Zirconium Diboride (ZrB₂), Germanium (Ge), Indium Phosphide, or Magnesium Oxide (MgO).

8. The semiconductor device according to claim 1, wherein the substrate is square, triangular, or rectangular.

9. The semiconductor device according to claim 1, further comprising one or more electrical contacts in electrical communication with the active layer.

10. The semiconductor device according to claim 9, further comprising at least two electrical contacts that are horizontally structured.

11. The semiconductor device according to claim 9, further comprising at least two electrical contacts that are vertically structured.

12. The semiconductor device according to claim 1, wherein the active area is adapted to emit light that is visible, ultraviolet (UV), or infrared.

13. A method of providing a semiconductor device, wherein the method comprises:
providing a substrate; and
fabricating an active area over the substrate, wherein the active area comprises at least one or more corner region having a non-orthogonal, angled edge.

14. The method according to claim 13, wherein providing a substrate comprises providing a silicon (Si), silicon on insulator (SOI), Silicon Carbide (SiC), Indium Phosphide, Germanium (Ge), sapphire, Gallium Arsenide (GaAs), Gallium Nitride (GaN), Aluminum Nitride (AlN), alumina (Al₂O₃), Lithium Aluminate (LiAlO₂), Zirconium Diboride (ZrB₂), or Magnesium Oxide (MgO) substrate.

15. The method according to claim 13, wherein providing a substrate comprises providing a carrier or growth substrate.

16. The method according to claim 13, wherein fabricating an active area comprises etching the active area over the substrate, and wherein the active area comprises a non-square and/or a non-rectangular shape.

17. The method according to claim 13, wherein the active area and the substrate comprise different shapes.

18. The method according to claim 13, further comprising depositing one or more electrical contacts over a portion of the active area.

19. A semiconductor device comprising:
a substrate; and
an active area disposed over the substrate, wherein the active area comprises an outer border having more than four linear side edges.

20. The semiconductor device according to claim 19, wherein at least two of the peripheral side edges form an obtuse angle.

21. The semiconductor device according to claim 19, wherein the device comprises a light emitting diode (LED) chip.

22. The semiconductor device according to claim 19, wherein the device comprises a laser diode, a Schottky diode, a Zener diode, a rectifying diode, an integrated circuit, an integrated circuit device, a photocell, a field-effect transistor (FET), a metal-oxide-semiconductor field-effect transistor (MOSFET), a monolithic microwave integrated circuit (MMIC), a high-electron-mobility transistor (HEMT), a sensor, a switch, a radio frequency (RF) device, a micro-device, or a broadband device.

23. The semiconductor device according to claim 19, wherein a portion of the outer border of the active area is partially rounded.

24. A semiconductor device comprising:
a substrate comprising a plurality of lateral side edges defining at least one corner; and
an active area disposed over the substrate, the active area comprising a plurality of outer edges and at least one corner region proximate to the corner of the substrate;
wherein a first distance disposed between an outermost edge of the corner region of the mesa and the corner of the substrate is at least approximately three (3) times greater than a second distance disposed between one outer edge of the mesa and one lateral side edge of the substrate.

25. The semiconductor device of claim 24, wherein the first distance is at least approximately three and a half (3.5) times greater than the second distance.

26. The semiconductor device of claim 24, wherein the first distance is at least approximately four (4) times greater than the second distance.

27. The semiconductor device of claim 24, wherein the first distance is at least approximately five (5) times greater than the second distance.
